(19) United States
(12) Patent Application Publication
(10) Pub. No.: US 2012/0321813 A1
(43) Pub. Date: Dec. 20, 2012

(54) THIN FILM DEPOSITION APPARATUS AND METHOD OF DEPOSITING THIN FILM BY USING THE SAME

(76) Inventors: Geum-Jong Roh, Yongin-City (KR); Tae-Wook Kim, Yongin-City (KR)

(21) Appl. No.: 13/441,657

(22) Filed: Apr. 6, 2012

(30) Foreign Application Priority Data
Jun. 17, 2011 (KR) 10-2011-0059171

(51) Int. Cl. B05D 3/14

(52) U.S. Cl. 427/532; 118/50.1

(57) ABSTRACT

A thin film deposition apparatus including a vacuum chamber; a substrate arranged inside the vacuum chamber; a container unit containing a deposition material and including a discharge opening to discharge the deposition material in a vaporized state; a first heating unit configured to heat at least a portion of the container unit; and a vapor discharge tube including a first opening connected to the discharge opening, and a second opening to discharge the vaporized deposition material to an outside of the vapor discharge tube, a length of a path connecting a center of the first opening to a center of the second opening along a centerline of the vapor discharge tube being greater than a length of a straight line interconnecting the centers of the first and second openings, the thin film deposition apparatus being configured to apply an electric field to the vapor discharge tube.

### CROSS-REFERENCE TO RELATED APPLICATION

This application claims priority to and the benefit of Korean Patent Application No. 10-2011-0059171, filed on Jun. 17, 2011 in the Korean Intellectual Property Office, the entire content of which is incorporated herein by reference.

### BACKGROUND

1. Field

Aspects of embodiments of the present invention relate to a thin film deposition apparatus and a method of depositing a thin film by using the same.

2. Description of the Related Art

Organic light emitting display apparatuses have been spotlighted as the next generation display apparatuses due to their advantageous features, such as their low driving voltage, light and thin design, wide viewing angle, excellent contrast ratio, and high response speed.

In order for an organic light emitting display apparatus to achieve high luminous efficiency, inter-layers, such as an electron injection layer (EIL), an electron transport layer (ETL), a hole transport layer (HTL), and a hole injection layer (HIL), are selectively arranged between each electrode and a light emitting layer.

Generally, an organic thin film, such as a light emitting layer, is formed on a substrate of an organic light emitting display apparatus by using a deposition method.

In a typical case of using a deposition method, an organic thin film having a fine pattern is deposited by using a fine metal mask (FMM). However, in the case of deposition using a FMM, it is difficult to form an ultra-fine pattern due to deformation of the mask, as a shadow may be formed, and it is difficult to apply the method to a large-sized display device. Furthermore, a substrate and each of R, G, and B masks may not be properly aligned, and a pixel defining layer may be damaged by the mask.

### SUMMARY

According to an aspect of embodiments of the present invention, a thin film deposition apparatus for forming a thin film (e.g., an organic thin film) on a substrate without using a fine metal mask (FMM) deposits a charged vapor (e.g., a charged organic material vapor) onto the substrate. According to another aspect of embodiments of the present invention, a method of forming a thin film by using a thin film deposition apparatus includes depositing a charged vapor (e.g., a charged organic material vapor) onto a substrate.

According to an embodiment of the present invention, a thin film deposition apparatus includes: a vacuum chamber configured to maintain a vacuum therein; a substrate arranged inside the vacuum chamber, the thin film deposition apparatus being configured to apply a voltage to at least a portion of the substrate; a container unit containing a deposition material and including a discharge opening to discharge the deposition material in a vaporized state; a first heating unit arranged corresponding to the container unit and configured to heat at least a portion of the container unit; and a vapor discharge tube including a first opening connected to the discharge opening, and a second opening to discharge the vaporized deposition material to an outside of the vapor discharge tube, a length of a path between a center of the first opening to a center of the second opening along a centerline of the vapor discharge tube being greater than a length of a straight line interconnecting the center of the first opening and the center of the second opening, the thin film deposition apparatus being configured to apply an electric field to the vapor discharge tube.

The vapor discharge tube may be formed of a conductive material.

The container unit and the vapor discharge tube may be integrally formed as a single body.

The thin film deposition apparatus may further include a thermal isolator containing the container unit, the vapor discharge tube, and the first heating unit therein.

The thin film deposition apparatus may further include a second heating unit arranged corresponding to the vapor discharge tube and configured to heat at least a portion of the vapor discharge tube.

The vapor discharge tube may have a spiral shape.

The vapor discharge tube may have a zigzag shape.

According to another embodiment of the present invention, a method of depositing a thin film includes: arranging a substrate in a vacuum chamber maintaining a vacuum therein; applying a voltage to at least a portion of the substrate; vaporizing a deposition material; applying an electric field to a space; charging the vaporized deposition material by passing the vaporized deposition material through the space having the electric field applied thereto along a path having a length between first and second openings of the space that is greater than a length of a straight line interconnecting the first and second openings; and depositing the charged vaporized deposition material on the substrate having the voltage applied thereto.

The path along which the vaporized deposition material is passed may be a spiral path.

The path along which the vaporized deposition material is passed may be a zigzag path.

The method may further include heating the vaporized deposition material passing through the space.

The method may further include additionally charging the vaporized deposition material that is uncharged in the space.

### BRIEF DESCRIPTION OF THE DRAWINGS

The above and other features and advantages of the present invention will become more apparent by describing in further detail some exemplary embodiments thereof with reference to the attached drawings in which:

FIG. 1 is a schematic sectional view of a deposition source of a thin film deposition apparatus according to an embodiment of the present invention;

FIG. 2 is a schematic diagram showing charged vapor in a vapor discharge tube of a thin film deposition apparatus according to an embodiment of the present invention;

FIG. 3 is a perspective view showing a portion of a deposition source of a thin film deposition apparatus, according to another embodiment of the present invention;

FIG. 4 is a schematic sectional view of a thin film deposition apparatus including the deposition source of FIG. 1, according to an embodiment of the present invention; and

FIG. 5 is a schematic sectional view showing a deposition material being deposited, according to an embodiment of the present invention.

### DETAILED DESCRIPTION

Some exemplary embodiments of the present invention will be described more fully hereinafter with reference to the accompanying drawings; however, embodiments of the present invention may be embodied in different forms and should not be construed as limited to the exemplary embodiments illustrated and set forth herein. Rather, these exemplary embodiments are provided by way of example for understanding of the invention and to convey the scope of the invention to those skilled in the art. As those skilled in the art would realize, the described embodiments may be modified in various ways, all without departing from the spirit or scope of the present invention.

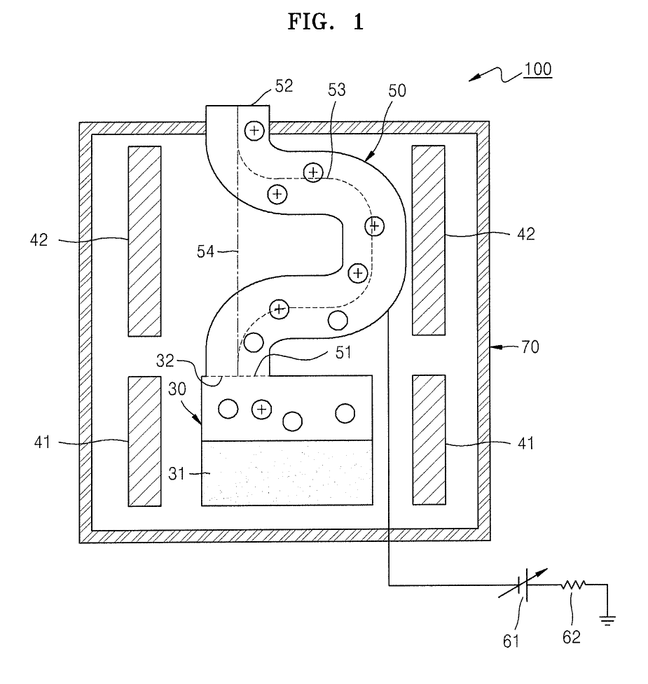

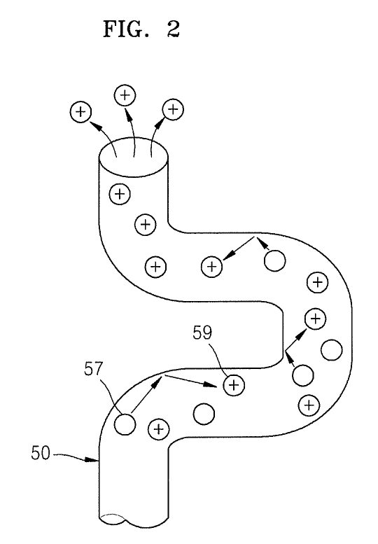

FIG. 1 is a schematic sectional view of a deposition source of a thin film deposition apparatus according to an embodiment of the present invention. FIG. 2 is a schematic diagram showing charged vapor in a vapor discharge tube of a thin film deposition apparatus according to an embodiment of the present invention.

Referring to FIG. 1, a deposition source 100 of a thin film deposition apparatus according to an embodiment of the present invention includes a container unit 30 housing a deposition material 31, a first heating unit 41 which is arranged to correspond to (e.g., is adjacent to) the container unit 30 and heats at least a portion of the container unit 30, a vapor discharge tube 50 to which an electric field is applied to form charged vapor, a second heating unit 42 for heating the vapor discharge tube 50, and a thermal isolator 70.

The container unit 30 contains the deposition material 31 and may be formed of a metal or a ceramic material, allowing the deposition material 31 to be easily heated. The container unit 30, in one embodiment, includes a discharge opening 32 at a top end of the container unit 30 through which the vaporized deposition material 31 may be discharged, as shown in FIG. 1.

The first heating unit 41 is configured to evaporate the deposition material 31 by heating the container unit 30 using a heating method, such as resistance heating, and is arranged to correspond to, such as being proximate, on, or adjacent to, the container unit 30. The first heating unit 41 may include a heater coil and may either be arranged to correspond to a portion of the container unit 30 to partially heat the container unit 30 or to correspond to or surround the entire container unit 30. The first heating unit 41 may be arranged outside the container unit 30 or may be integrated with the container unit 30.

Vaporized deposition material is discharged from the container unit 30 via the discharge opening 32.

The vapor discharge tube 50, in one embodiment, includes a first opening 51 and a second opening 52 that are arranged at two opposite ends of the vapor discharge tube 50. The first opening 51 is connected to the discharge opening 32 of the container unit 30, and the second opening 52 is open toward the outside of the deposition source 100 and discharges vapor.

The electric field may be applied to the vapor discharge tube 50, and the vapor may pass through the vapor discharge tube 50.

In one embodiment, to apply the electric field to the vapor discharge tube 50, a variable power source 61 and a resistor 62 are electrically connected to the vapor discharge tube 50. The intensity of the electric field to be applied may be adjusted by using the variable power source 61. In one embodiment, to apply the electric field to the vapor discharge tube 50, the vapor discharge tube 50 is formed of a conductive material.

Vaporized deposition material 31 is electrically charged by the electric field applied to the vapor discharge tube 50 as the vapor passes through the vapor discharge tube 50. Although an embodiment is depicted in FIG. 1 in which vapor is electrically charged with positive charges, in another embodiment, vapor may be electrically charged with negative charges if negative charges are applied to the surface of the vapor discharge tube 50.

In one embodiment, a length L of a line 53 which connects the center of the first opening 51 to the center of the second opening 52 along the centerline of the vapor discharge tube 50 and a length d of a straight line 54 interconnecting the center of the first opening 51 and the second opening 52 may satisfy Inequality 1 below.

L>d Inequality 1

In one embodiment, since the vapor discharge tube 50 has a curved shape, vapor may be more definitely electrically charged as it passes along a curved path that is longer than a straight-line path. Further, the vapor discharge tube 50 having a curved shape may prevent or substantially prevent uncharged vapor from moving vertically upward and being discharged directly to the outside through the second opening 52, and thus a charging rate of vapor may be improved.

Referring to FIG. 2, vapor passing through the vapor discharge tube 50 includes charged vapor 59 and uncharged vapor 57.

Since the electric field is applied to the vapor discharge tube 50, the charged vapor 59 passes according to Brownian motion without being attached to the vapor discharge tube 50 because the surface of the vapor discharge tube 50 is charged with a same polarity as that of the vapor. However, the uncharged vapor 57 may approach the surface of the vapor discharge tube 50, and thus the uncharged vapor 57 is additionally charged by the electric field applied to the vapor discharge tube 50.

Therefore, as vapor passes through the vapor discharge tube 50, which is formed to be longer than a straight path, the vapor is charged, and uncharged vapor is additionally charged. As a result, the charging rate of the vapor may be improved. However, a structure of the vapor discharge tube 50 according to embodiments of the present invention is not limited to the structure shown in FIG. 1.

In one embodiment, the deposition source 100 further includes the second heating unit 42 which is arranged to correspond to (e.g., is proximate or adjacent to) the vapor discharge tube 50 for heating the vapor discharge tube 50. In one embodiment, the second heating unit 42 may include a heater coil and may be arranged to correspond to, such as proximate, on, or adjacent to, a portion of the vapor discharge tube 50 to partially heat the vapor discharge tube 50 or to correspond to or surround the entire vapor discharge tube 50.

The second heating unit 42 heats the vapor discharge tube 50 to increasingly activate the motion of the vapor and to prevent or reduce exhaustion of the vapor by preventing or substantially preventing the vapor from being attached to the surface of the vapor discharge tube 50.

In one embodiment, the second heating unit 42 may be connected to the first heating unit 41 to form a single body or, alternatively, may be separate from the first heating unit 41. In one embodiment, the first heating unit 41 and the second heating unit 42 may maintain temperatures of the container unit 30 and the vapor discharge tube 50 at about 200° C. to about 400° C. according to the deposition material 31.

In one embodiment, the thermal isolator 70 contains the container unit 30, the vapor discharge tube 50, the first heating unit 41, and the second heating unit 42 therein. The thermal isolator 70 prevents or substantially prevents the temperature inside the thermal isolator 70 from affecting the outside of the deposition source 100. In one embodiment, the temperature inside the thermal isolator 70 may be maintained constant to negate effects from the outside. In one embodiment, the thermal isolator 70 may not only contain the container unit 30, the vapor discharge tube 50, the first heating unit 41, and the second heating unit 42 sealed therein, but may also be arranged as a covering unit for covering at least one of the container unit 30, the vapor discharge tube 50, the first heating unit 41, and the second heating unit 42.

The thermal isolator 70 is described above and shown in FIG. 1 as a component of the deposition source 100. However, the present invention is not limited thereto and, in other embodiments, the thermal isolator 70 may be omitted or may be selectively arranged.

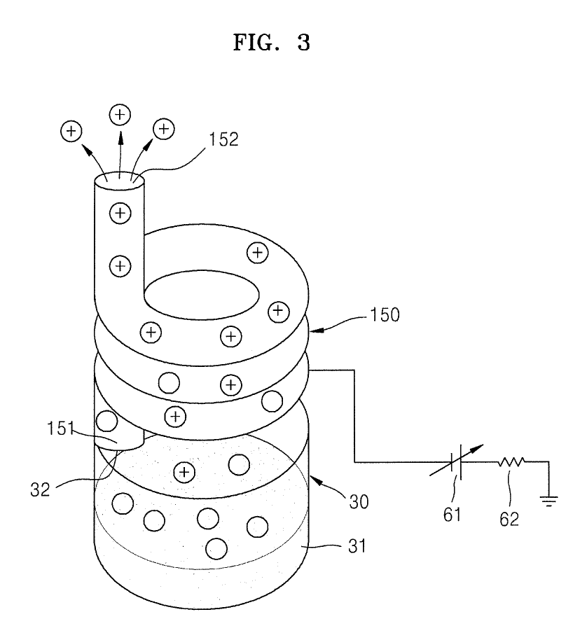

FIG. 3 is a perspective view showing a portion of a deposition source of a thin film deposition apparatus, according to another embodiment of the present invention.

Referring to FIG. 3, a deposition source according to another embodiment is the same as the deposition source described above and shown in FIG. 1 except that a vapor discharge tube 150 has a spiral shape. In the vapor discharge tube 150 having a spiral shape, a path in which vapor passes is longer than that of the vapor discharge tube 50 described above and shown in FIG. 1, and thus the charging rate of the vapor may be further improved. The vapor discharge tube 150 has a first opening 151 and a second opening 152 that are arranged at two opposite ends of the vapor discharge tube 150. Other components of the deposition source of FIG. 3 are the same as those of the deposition source 100 described above and shown in FIG. 1, and thus detailed descriptions thereof are not repeated herein.

Although vapor is depicted in the drawings as being electrically charged with positive charges in the above-described embodiments, the vapor may be electrically charged with negative charges.

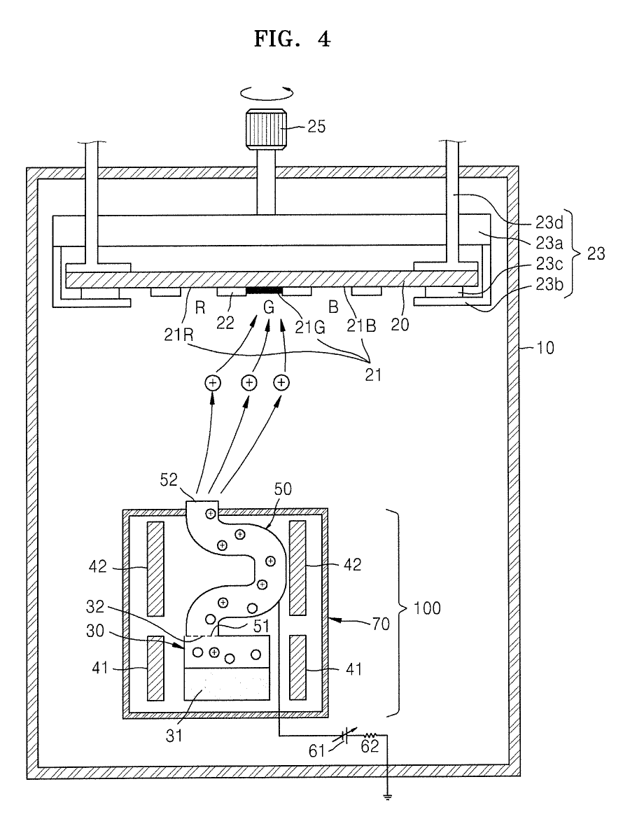

FIG. 4 is a schematic sectional view of a thin film deposition apparatus including the deposition source 100, according to an embodiment of the present invention.

The thin film deposition apparatus, in one embodiment, includes a vacuum chamber 10 inside of which is maintained a vacuum, a substrate 20 on which the deposition material 31 is to be deposited in the vacuum chamber 10, a substrate supporting unit 23 for supporting the substrate 20, and the deposition source 100.

The substrate supporting unit 23, in one embodiment, includes a substrate supporting base 23a connected to a substrate rotating unit 25, a substrate holder 23b for supporting two edges of the substrate 20 from below the substrate 20, and a substrate pressing unit 23d which may be connected to an external driving unit for elevating up and down and pressing the substrate 20 toward the substrate holder 23b at a location corresponding to the substrate holder 23b. The substrate rotating unit 25 may rotate the substrate 20 such that uniformity of the deposition material 31 deposited on the substrate 20 may be improved. An electrode and at least one ground wire are arranged at a region 23c of the substrate holder 23b.

However, the substrate supporting unit 23 is not limited to the embodiment shown in FIG. 4, and various other structures (e.g., an electrostatic chuck) may be employed for supporting the substrate 20.

The substrate 20 is arranged to face the second opening 52 of the vapor discharge tube 50, and wires for applying a gate signal to a sub-pixel 21 or ground wires may be arranged at a region of the substrate 20 corresponding to the region 23c of the substrate holder 23b.

The substrate 20, in one embodiment, includes R, G, and B sub-pixels 21R, 21G, and 21B and a pixel defining layer (PDL) 22. The vaporized deposition material 31 may be deposited on each of the R, G, and B sub-pixels 21R, 21G, and 21B.

The deposition source 100 is arranged to face the substrate 20.

According to the embodiment shown in FIG. 4, the deposition material 31 for the G sub-pixel 21G is housed in the container unit 30. In one embodiment, a gate signal is applied to only a wire connected to the G sub-pixel 21G, and ground signals are applied to the R and B sub-pixels 21R and 21B.

Charged vapor travels toward the substrate 20 by an electric field due to an electric signal applied to the substrate 20 and, in one embodiment, is only deposited on the G sub-pixel 21G. Charged vapor may be deposited on the R sub-pixel 21R or the B sub-pixel 21B in a similar manner.

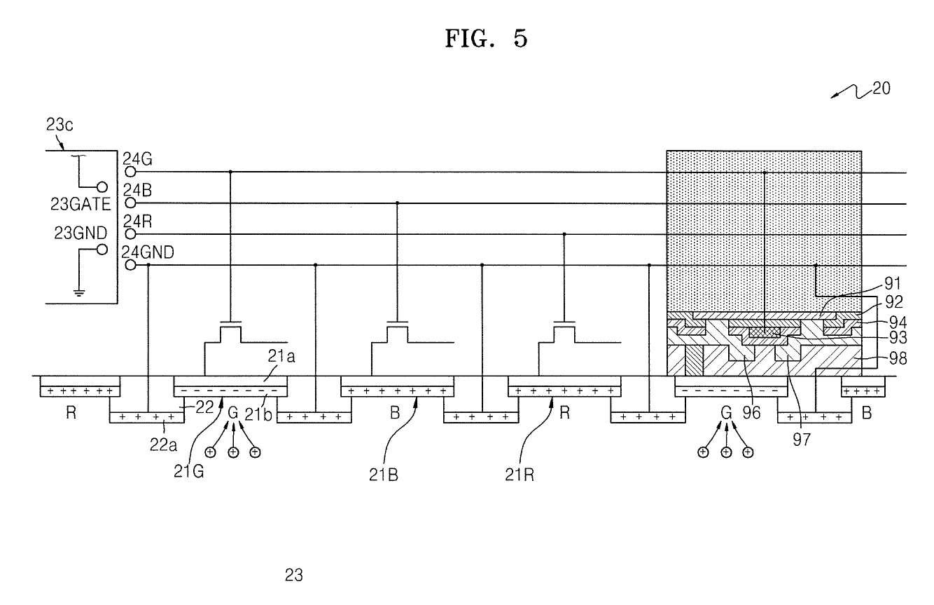

FIG. 5 is a schematic sectional view showing a deposition material being deposited, according to an embodiment of the present invention.

Referring to FIG. 5, in one embodiment, wires 24R, 24G, 24B, and 24GND are respectively connected to the R, G, and B sub-pixels 21R, 21G, and 21B, and the PDL 22, and may respectively apply gate signals or ground signals to the R, G, and B sub-pixels 21R, 21G, and 21B, and the PDL 22 which are formed at a region of the substrate 20, whereas an electrode 23GATE and at least one ground wire 23GND are formed at the region 23c of the substrate holder 23b corresponding to the wires 24R, 24G, 24B, and 24GND.

A buffer layer is formed on the substrate 20, and a semiconductor layer 91 including an active channel layer and an ohmic contact layer is formed on a region of the buffer layer. A gate insulation layer 92 and a gate electrode 93 are sequentially patterned and formed on the semiconductor layer 91. An interlayer insulation layer 94 is formed on the gate electrode 93 to expose the ohmic contact layer of the semiconductor layer 91, and source and drain electrodes 96 and 97 arranged to contact the exposed ohmic contact layer are formed on a region of the interlayer insulation layer 94.

Furthermore, a planarizing layer 98 is formed on the interlayer insulation layer 94, and a via hole is formed in the planarizing layer 98 (e.g., by partially etching the planarizing layer 98) such that the source and drain electrodes 96 and 97 are electrically connected to first electrode layers 21a and 21b via the via hole. The first electrode layers 21a and 21b are formed at a region of the planarizing layer 98, and the PDL 22 having an opening for exposing at least portions of the first electrode layers 21a and 21b is formed on the planarizing layer 98.

The first electrode layers 21a and 21b, in one embodiment, are formed as double layers. The lower first electrode layer 21a connected to the ohmic contact layer may function as a reflective film. The upper first electrode layer 21b has a large work function and may be formed of ITO, IZO, or the like.

A metal film 22a is formed on the PDL 22. The metal film 22a functions as a buffer for helping formation of an electric field between a sub-pixel to which a gate signal is applied and other sub-pixels, prevents or substantially prevents deposition of the deposition material 31, and improves contrast. The metal film 22a may be formed of chrome, silver, aluminum, etc.

FIG. 5 shows vaporized deposition material being deposited on the G sub-pixel 21G. Here, a gate signal is only applied to the G sub-pixel 21G from the gate electrode 23GATE of the region 23c of the substrate holder 23b, whereas ground signals are applied to the R and B sub-pixels 21R and 21B. As a result, charged vapor with positive charges is deposited only on the G sub-pixel 21G of which the first electrode layer 21b is charged with negative charges. Here, ground signals are applied to the R and B sub-pixels 21R and 21B and the metal film 22a that is formed on the PDL 22, so that the R and B sub-pixels 21R and 21B and the metal film 22a are charged with positive charges. As a result, the vaporized deposition material is not deposited on the R and B sub-pixels 21R and 21B and the metal film 22a.

As described above, a thin film deposition apparatus and method according to embodiments of the present invention may form a deposition material at a desired location without using a mask.

While the present invention has been particularly shown and described with reference to some exemplary embodiments thereof, it will be understood by those of ordinary skill in the art that various changes in form and details may be made therein without departing from the spirit and scope of the present invention as set forth in the following claims.

What is claimed is:

1. A thin film deposition apparatus comprising:
a vacuum chamber configured to maintain a vacuum therein;
a substrate arranged inside the vacuum chamber, wherein the thin film deposition apparatus is configured to apply a voltage to at least a portion of the substrate;
a container unit containing a deposition material and including a discharge opening to discharge the deposition material in a vaporized state;
a first heating unit arranged corresponding to the container unit and configured to heat at least a portion of the container unit; and
a vapor discharge tube including a first opening connected to the discharge opening, and a second opening to discharge the vaporized deposition material to an outside of the vapor discharge tube, wherein a length of a path between a center of the first opening to a center of the second opening along a centerline of the vapor discharge tube is greater than a length of a straight line interconnecting the center of the first opening and the center of the second opening, and wherein the thin film deposition apparatus is configured to apply an electric field to the vapor discharge tube.

2. The thin film deposition apparatus of claim 1, wherein the vapor discharge tube is formed of a conductive material.

3. The thin film deposition apparatus of claim 1, wherein the container unit and the vapor discharge tube are integrally formed as a single body.

4. The thin film deposition apparatus of claim 1, further comprising a thermal isolator containing the container unit, the vapor discharge tube, and the first heating unit therein.

5. The thin film deposition apparatus of claim 1, further comprising a second heating unit arranged corresponding to the vapor discharge tube and configured to heat at least a portion of the vapor discharge tube.

6. The thin film deposition apparatus of claim 1, wherein the vapor discharge tube has a spiral shape.

7. The thin-film depositing apparatus of claim 1, wherein the vapor discharge tube has a zigzag shape.

8. A method of depositing a thin film, the method comprising:
arranging a substrate in a vacuum chamber maintaining a vacuum therein;
applying a voltage to at least a portion of the substrate;
vaporizing a deposition material;
applying an electric field to a space;
charging the vaporized deposition material by passing the vaporized deposition material through the space having the electric field applied thereto along a path having a length between first and second openings of the space that is greater than a length of a straight line interconnecting the first and second openings; and
depositing the charged vaporized deposition material on the substrate having the voltage applied thereto.

9. The method of claim 8, wherein the path along which the vaporized deposition material is passed is a spiral path.

10. The method of claim 8, wherein the path along which the vaporized deposition material is passed is a zigzag path.

11. The method of claim 8, further comprising heating the vaporized deposition material passing through the space.

12. The method of claim 8, further comprising additionally charging the vaporized deposition material that is uncharged in the space.
